(19) United States
(12) Patent Application Publication
(10) Pub. No.: US 2011/0281430 A1
(43) Pub. Date: Nov. 17, 2011

(54) WAFER LEVEL PACKAGE AND METHOD OF MANUFACTURING THE SAME

(75) Inventor: Seung-Seoup LEE, Yongin-si (KR)

(73) Assignee: Samsung Electro-Mechanics Co., Ltd., Gyunggi-do (KR)

(21) Appl. No.: 13/192,121

(22) Filed: Jul. 27, 2011

Related U.S. Application Data
(62) Division of application No. 12/504,143, filed on Jul. 16, 2009.

(30) Foreign Application Priority Data
Jan. 28, 2009 (KR) 10-2009-0006617

(51) Int. Cl. H01L 21/28

(52) U.S. Cl. 438/612; 257/E21.158

(57) ABSTRACT

A method of manufacturing a wafer level package can include: forming an indentation, by etching one side of a semiconductor chip, on one side of which a chip pad is formed; forming a rewiring pattern, which is electrically connected with the chip pad and which includes a post pad having a corrugated shape in correspondence with the indentation, by selectively adding a conductive material on one side of the semiconductor chip; forming a sacrificial layer on one side of the semiconductor chip such that a window is formed in the sacrificial layer that completely or partially uncovers the post pad; forming a conductive post on the post pad, by filling the window with a conductive material; and removing the sacrificial layer. This method can be used to produce a wafer level package having a post structure that provides greater strength against lateral shear stresses.

### CROSS-REFERENCE TO RELATED APPLICATIONS

This application claims the benefit of Korean Patent Application No. 10-2009-0006617, filed with the Korean Intellectual Property Office on Jan. 28, 2009, the disclosure of which is incorporated herein by reference in its entirety.

### BACKGROUND

1. Technical Field

The present invention relates to a wafer level package and to a method of manufacturing the wafer level package.

2. Description of the Related Art

The trend in the electronics industry is to manufacture smaller, lighter products that provide faster speed, greater functionality, and higher performance, with higher reliability and lower costs. An important technology that makes this possible is packaging technology, among which the wafer level package (WLP) technology in particular is used to realize smaller sizes, lighter weight, higher performance, etc.

In general, a rewiring pattern may be formed in a wafer level package, to more easily implement an electrical connection when the package is mounted on a board. Also, column-shaped posts may be formed on the rewiring pattern that form the electrical connection with the board.

However, when the wafer level package is mounted on a board, the difference in the rates of thermal expansion between the package and the board can generate thermal stresses, which may be concentrated on the posts that connect the wafer level package with the board. As such, there may be occurrences in which the posts are damaged or destroyed by these stresses, or in which cracks are formed in the posts.

### SUMMARY

An aspect of the invention is to provide a wafer level package, and a method of manufacturing the wafer level package, in which the posts that connect the package to the board are highly resistant to stresses, especially lateral shear stresses.

One aspect of the invention provides a method of manufacturing a wafer level package that includes: forming an indentation, by etching one side of a semiconductor chip, on one side of which a chip pad is formed; forming a rewiring pattern, which is electrically connected with the chip pad and which includes a post pad having a corrugated shape in correspondence with the indentation, by selectively adding a conductive material on one side of the semiconductor chip; forming a sacrificial layer on one side of the semiconductor chip such that a window is formed in the sacrificial layer that completely or partially uncovers the post pad; forming a conductive post on the post pad, by filling the window with a conductive material; and removing the sacrificial layer.

In certain embodiments, the method can further include, after the operation of removing the sacrificial layer, an additional operation of stacking a molding material, which surrounds the lateral surfaces of the conductive post, on one side of the semiconductor chip.

Forming the sacrificial layer can include: stacking a photoresist on one side of the semiconductor chip; and forming the window, which completely or partially uncovers the post pad, by selectively exposing and developing the photoresist.

Also, forming the conductive post can include: performing electroplating, using the post pad as an electrode to form the conductive post.

Another aspect of the invention provides a method of manufacturing a wafer level package that includes: forming a rewiring pattern electrically connected with a chip pad, by selectively adding a conductive material on one side of a semiconductor chip that has the chip pad formed on the one side; forming a post pad having a corrugated shape, by etching a portion of the rewiring pattern; forming a sacrificial layer on one side of the semiconductor chip such that a window is formed in the sacrificial layer that completely or partially uncovers the post pad; forming a conductive post on the post pad, by filling the window with a conductive material; and removing the sacrificial layer.

Here, the method can further include, after the operation of removing the sacrificial layer, an additional operation of stacking a molding material, which surrounds the lateral surfaces of the conductive post, on one side of the semiconductor chip.

Forming the sacrificial layer can include: stacking a photoresist on one side of the semiconductor chip; and forming the window, which completely or partially uncovers the post pad, by selectively exposing and developing the photoresist.

Also, forming the conductive post can include: performing electroplating, using the post pad as an electrode to form the conductive post.

Still another aspect of the invention provides a wafer level package that includes: a semiconductor chip, on which a chip pad is formed, and in which an indentation is formed; a rewiring pattern, which is electrically connected with the chip pad, and which includes a post pad having a corrugation formed in correspondence with the indentation; and a conductive post placed on the post pad.

Here, the wafer level package can further include a molding material stacked on the semiconductor chip to surround the lateral surfaces of the conductive post.

The indentation can be shaped as a multiple number of concentric rings, and the corrugation in the post pad can be shaped as concentric circles in correspondence with the indentation.

Also, a conductive bump attached to the conductive post can additionally be included.

Yet another aspect of the invention provides a wafer level package that includes: a semiconductor chip, on which a chip pad is formed; a rewiring pattern, which is electrically connected with the chip pad, and which includes a post pad formed by selective etching so that a corrugation is formed therein; and a conductive post placed on the post pad.

In certain embodiments, the wafer level package can further include a molding material stacked on the semiconductor chip to surround the lateral surfaces of the conductive post.

The indentation can be shaped as a multiple number of concentric rings, and the corrugation in the post pad can be shaped as concentric circles in correspondence with the indentation.

The wafer level package can further include a conductive bump attached to the conductive post.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow diagram illustrating a method of manufacturing a wafer level package according to a first disclosed embodiment of the invention.

FIG. 2, FIG. 3, FIG. 4, FIG. 5, FIG. 6, FIG. 7, and FIG. 8 are cross-sectional views each illustrating an operation in a method of manufacturing a wafer level package according to the first disclosed embodiment of the invention.

FIG. 9 is a flow diagram illustrating a method of manufacturing a wafer level package according to a second disclosed embodiment of the invention.

FIG. 10, FIG. 11, FIG. 12, FIG. 13, FIG. 14, FIG. 15, FIG. 16, and FIG. 17 are cross-sectional views each illustrating an operation in a method of manufacturing a wafer level package according to the second disclosed embodiment of the invention.

FIG. 18 is a cross-sectional view illustrating a wafer level package according to the first disclosed embodiment of the invention.

FIG. 19 is a plan view illustrating a rewiring pattern in a wafer level package according to the first disclosed embodiment of the invention.

FIG. 20 is a cross-sectional view illustrating a wafer level package according to the second disclosed embodiment of the invention.

FIG. 21 is a plan view illustrating a rewiring pattern in a wafer level package according to the second disclosed embodiment of the invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first” and “second,” etc., may be used to describe various elements, such elements must not be limited to the above terms. The above terms are used only to distinguish one element from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The wafer level package and method of manufacturing the wafer level package according to certain embodiments of the invention will be described below in more detail with reference to the accompanying drawings. Those elements that are the same or are in correspondence are rendered the same reference numeral regardless of the figure number, and redundant descriptions are omitted.

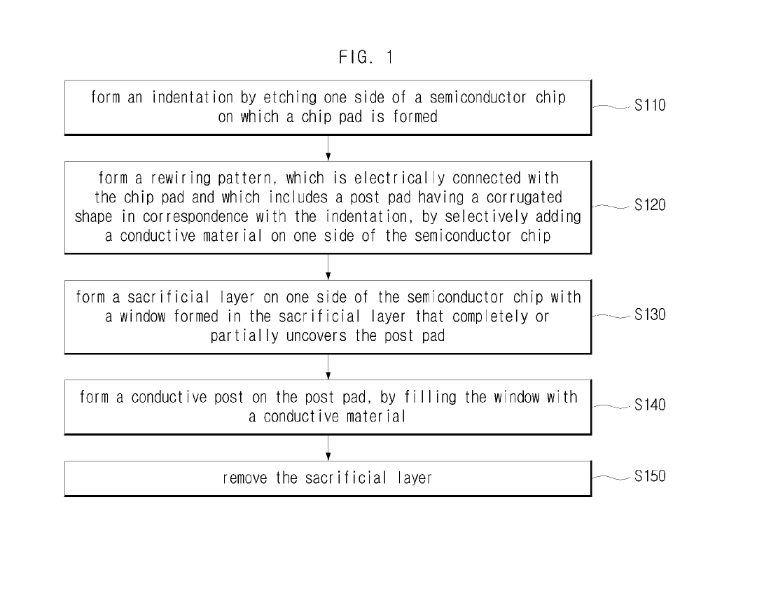

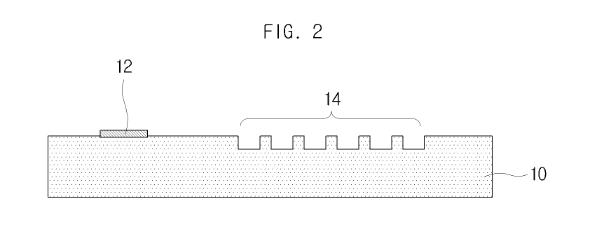

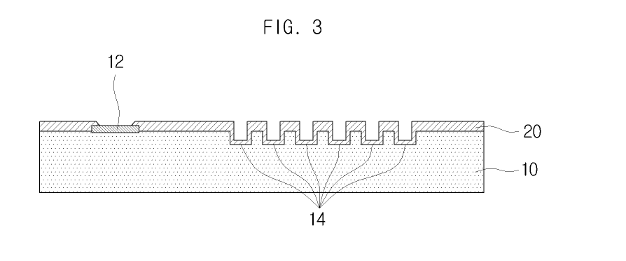

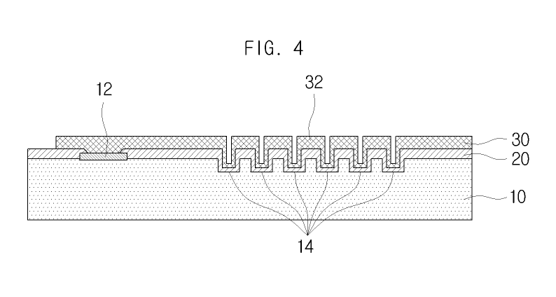

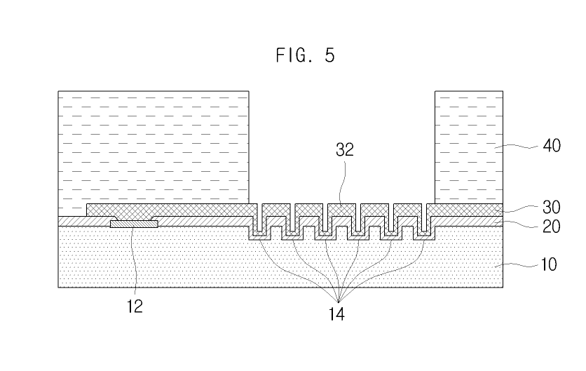

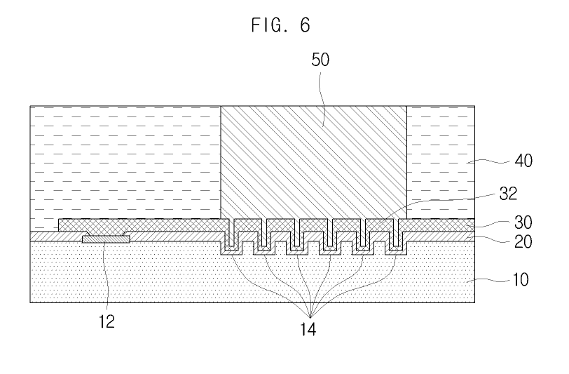

FIG. 1 is a flow diagram illustrating a method of manufacturing a wafer level package according to a first disclosed embodiment of the invention, and FIG. 2 through FIG. 8 are cross-sectional views each illustrating an operation in a method of manufacturing a wafer level package according to the first disclosed embodiment of the invention.

Illustrated in FIG. 2 through FIG. 8 are a semiconductor chip 10, a chip pad 12, indentations 14, a passivation layer 20, a rewiring pattern 30, a post pad 32, a sacrificial layer 40, a conductive post 50, a molding material 55, and a conductive bump 60.

A method of manufacturing a wafer level package according to a first disclosed embodiment of the invention may include: forming an indentation 14, by etching one side of a semiconductor chip 10 on which a chip pad 12 is formed; forming a rewiring pattern 30 that is electrically connected with the chip pad 12 and includes a post pad 32 having a corrugated shape in correspondence with the indentation 14 by selectively adding a conductive material on one side of the semiconductor chip 10; forming a sacrificial layer 40 on one side of the semiconductor chip 10 with a window formed in the sacrificial layer 40 that completely or partially uncovers the post pad 32; forming a conductive post 50 on the post pad 32 by filling the window with a conductive material; and removing the sacrificial layer 40. By forming a corrugation to increase the area supporting the conductive post 50, the wafer level package can be manufactured with a post structure that provides greater strength against stresses occurring when mounting on a board, particularly shear stresses in the lateral direction.

Looking at a method of manufacturing a wafer level package according to this embodiment, first, one side of the semiconductor chip 10 on which a chip pad 12 is formed may be etched to form an indentation 14 (operation S110), as illustrated in FIG. 2. In order to form a post pad 32 that includes a corrugation to firmly secure the conductive post 50, the indentation 14 may be formed as a base for the corrugation, at the position where the conductive post 50 is to be formed. Here, the size and interval of the indentation 14 may be determined in consideration of the thicknesses of the passivation layer 20 and rewiring pattern 30, which will be formed later. Also, the indentation 14 may be formed in consideration of the shape of the corrugation suitable for supporting the post. This particular embodiment may include a multiple number of indentations 14, in order to form a corrugation shaped as concentric circles with alternating troughs and ridges.

Next, as illustrated in FIG. 4, a conductive material may be added selectively on one side of the semiconductor chip 10 to form a rewiring pattern 30 that is electrically connected with the chip pad 12 and includes a post pad 32 having a corrugated shape in correspondence with the indentation 14 (operation S120). This operation is to form the post pad 32, on which the conductive post 50 will be placed, and to form the rewiring pattern 30, to connect the post pad 32 with the chip pad 12. Forming the rewiring pattern 30 having the post pad 32 can be performed by building up a conductive material to a particular thickness on the semiconductor chip 10 using a method such as plating, metal sputtering, etc. As a result, the post pad 32 may be formed with a corrugated shape corresponding to the indentations 14 formed in the semiconductor chip 10. Here, the thickness may be maintained at a particular value that does not level out the corrugation and does not cause the corrugated portions to stick together.

Before forming the rewiring pattern 30, a passivation layer 20 made of an oxide film or a nitride film, for example, can additionally be formed, as illustrated in FIG. 3, to protect the surface of the semiconductor chip 10 and provide electrical insulation. It is also possible to form the indentations 14 in the semiconductor chip after forming the passivation layer 20.

Next, as illustrated in FIG. 5, a sacrificial layer 40 may be formed on one side of the semiconductor chip 10 with a window formed in the sacrificial layer 40 that completely or partially uncovers the post pad 32 (operation S130). To form the conductive post 50 that will be placed on the post pad 32, the window is formed over the post pad 32 to serve as a cast for the conductive post 50.

Here, the sacrificial layer 40 can be formed by stacking a photoresist. In a specific example, a photoresist may be stacked on one side of the semiconductor chip 10, and the stacked photoresist may be selectively exposed and developed, to form the window that completely or partially uncovers the post pad 32. The photoresist may be a photosensitive material that changes its resistance to certain solvents upon receiving light. Thus, by selective exposure and development, a window can be formed that exposes the post pad. Here, the photoresist can be a thick film (such as DFR—dry film resist) attached to the semiconductor chip 10 or a liquid material coated on the semiconductor chip 10.

Next, as illustrated in FIG. 6, a conductive material may be filled in the window to form the conductive post 50 on the post pad 32 (operation S140). By filling a conductive material in the window formed in the sacrificial layer 40, a conductive post 50 may be formed that connects electrically to the board. Because of the corrugation formed in the post pad 32 that supports the conductive post 50, the conductive post 50 may be supported across a larger area, and thus may be firmly secured to the post pad 32. As a result, the conductive post 50 may better resist stresses that occur when the wafer level package is mounted on the board. In particular, even when lateral shear stresses are applied due to the difference in rates of thermal expansion, the conductive post 50 can be effectively prevented from becoming detached from the post pad 32 and from cracking at the contact surfaces, as the lower end of the conductive post 50 is lodged in the post pad 32.

Filling the conductive material can be performed by electroplating, in which case the post pad 32 can be used as an electrode for the electroplating. This can facilitate the procedures for filling the conductive material in the window and forming the conductive post 50.

Next, as illustrated in FIG. 7, the sacrificial layer 40 may be removed (operation S150). The sacrificial layer 40, which was stacked for forming the conductive post 50, may be removed after placing the conductive post 50. According to the material of the sacrificial layer 40, the sacrificial layer 40 may be separated from the semiconductor chip 10 by exposure to ultraviolet rays or by chemical etching.

As illustrated in FIG. 8, a molding material 55 surrounding the conductive post 50 can additionally be stacked, in order to reinforce the strength of the conductive post 50. The molding material 55 may be stacked on one side of the semiconductor chip 10 to protect the rewiring pattern 30 and support the conductive post 50. Here, an epoxy can be used as the molding material 55, which may be applied and molded using a spray coating method.

Also, after stacking the molding material 55, an additional grinding process can be performed to level the top of the conductive post 50. As the top of the conductive post 50 contacting the board is evened out, the reliability of the electrical connection may be improved.

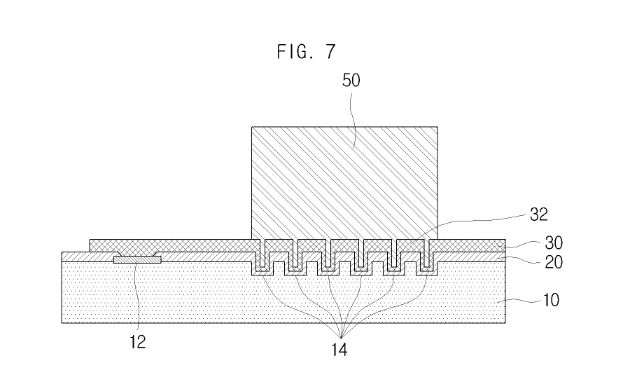

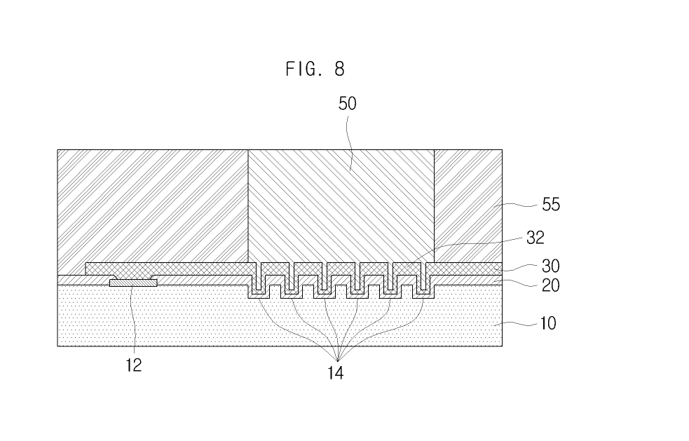

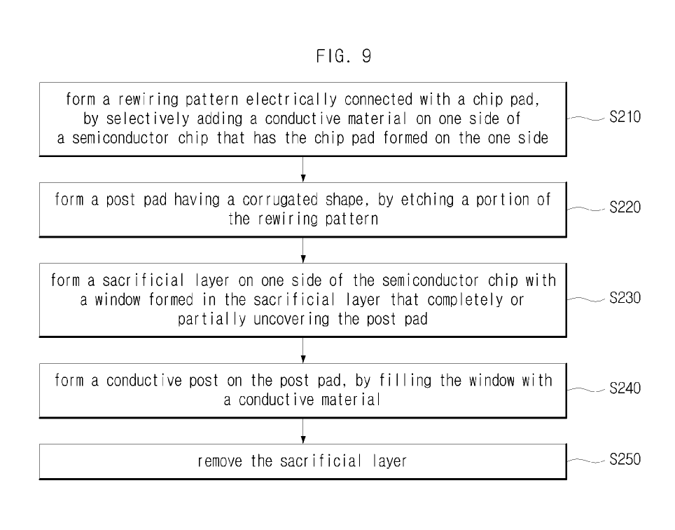

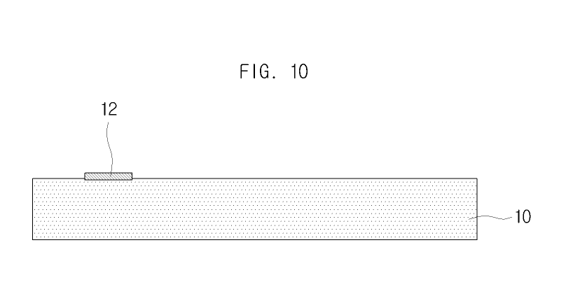

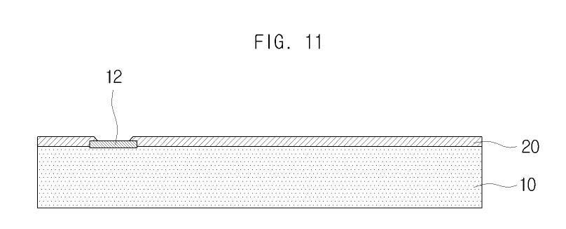

FIG. 9 is a flow diagram illustrating a method of manufacturing a wafer level package according to a second disclosed embodiment of the invention, and FIG. 10 through FIG. 17 are cross-sectional views each illustrating an operation in a method of manufacturing a wafer level package according to the second disclosed embodiment of the invention.

A method of manufacturing a wafer level package according to the second disclosed embodiment of the invention may include: forming a rewiring pattern 30 electrically connected with a chip pad 12, by selectively adding a conductive material on one side of a semiconductor chip 10 that has the chip pad 12 formed on the one side; forming a post pad 32 having a corrugated shape, by etching a portion of the rewiring pattern 30; forming a sacrificial layer 40 on one side of the semiconductor chip 10 such that a window is formed in the sacrificial layer 40 that completely or partially uncovers the post pad 32; forming a conductive post 50 on the post pad 32, by filling the window with a conductive material; and removing the sacrificial layer 40. By forming a corrugation to increase the area supporting the conductive post 50, the wafer level package can be manufactured with a post structure that provides greater strength against stresses occurring when mounting on a board, especially shear stresses in the lateral direction.

This embodiment differs from the previously disclosed embodiment in that the corrugation may be formed by etching the post pad 32 after forming the rewiring pattern 30.

This embodiment will be described mainly with respect to elements that are different from those of the previously disclosed embodiment. The description of those elements that are substantially the same as those of the previously disclosed embodiment will not be repeated.

As illustrated in FIG. 10 through FIG. 12, in this particular embodiment, a conductive material may first be built up selectively on one side of a semiconductor chip 10 on which a chip pad 12 is formed, to form a rewiring pattern 30 electrically connected with the chip pad 12 (operation S210). Unlike the first disclosed embodiment, there is no indentation 14 formed in the semiconductor chip 10 at the position where the post pad 32 is formed.

Referring to FIG. 11, before forming the rewiring pattern 30, a passivation layer 20 made of an oxide film or a nitride film, for example, can additionally be formed to protect the surface of the semiconductor chip 10 and provide electrical insulation

Next, as illustrated in FIG. 13, a portion of the rewiring pattern 30 may be etched to form a post pad 32 having a corrugated shape (operation S220). In this particular embodiment, a multiple number of concentric indentations may be formed in the rewiring pattern 30, so that the post pad 32 may be formed with a corrugation shaped as concentric circles. In this way, the post pad 32 can be made to support a conductive post 50 over a large area, similar to the previously disclosed embodiment.

Next, as illustrated in FIG. 14 through FIG. 16, a sacrificial layer 40 may be formed on one side of the semiconductor chip 10 such that a window completely or partially uncovering the post pad 32 is formed in the sacrificial layer 40 (operation S230), a conductive material may be filled in the window to form the conductive post 50 placed on the post pad 32 (operation S240), and then the sacrificial layer 40 may be removed (operation S250). Here, filling in the conductive material can be performed by electroplating, where the post pad 32 can be used as an electrode for the electroplating.

As illustrated in FIG. 17, a molding material 55 that surrounds the conductive post 50 can additionally be stacked, in order to reinforce the conductive post 50.

Also, after stacking the molding material 55, an additional grinding process can be performed to even out the top of the conductive post 50.

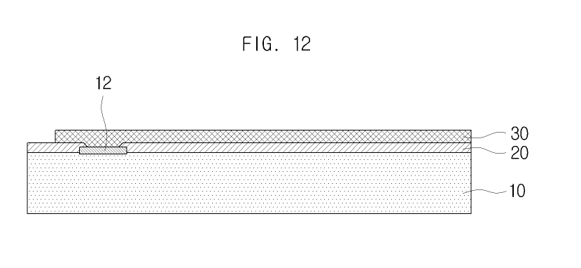

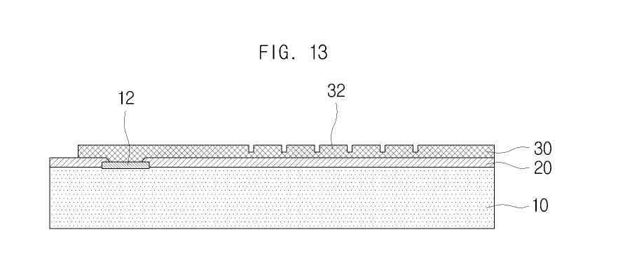

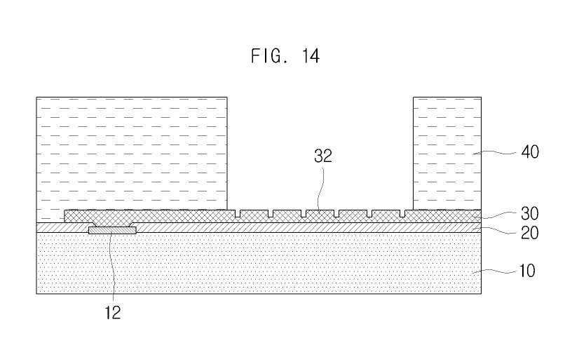

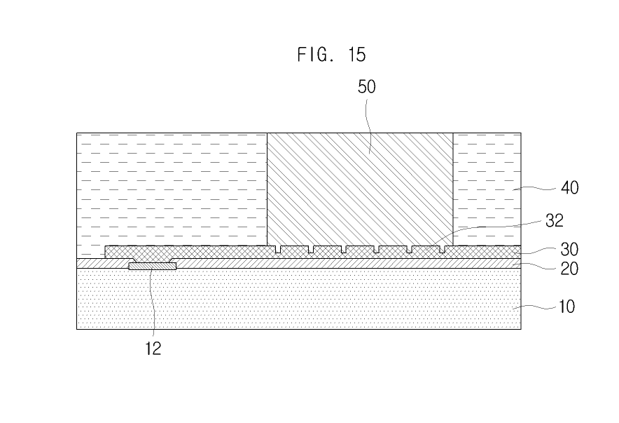

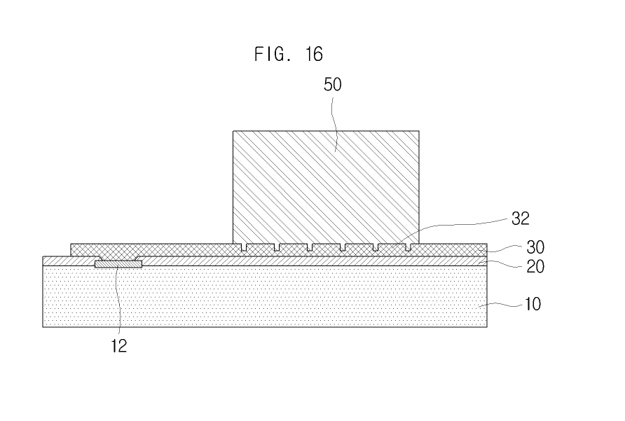

FIG. 18 is a cross-sectional view illustrating a wafer level package according to the first disclosed embodiment of the invention, and FIG. 19 is a plan view illustrating the rewiring pattern 30 in a wafer level package according to the first disclosed embodiment of the invention.

A wafer level package according to the first disclosed embodiment of the invention may include: a semiconductor chip 10 that includes a chip pad 12 and an indentation 14, a rewiring pattern 30 that is electrically connected with the chip pad 12 and includes a post pad 32 in which a corrugation is formed in correspondence with the indentation 14; and a conductive post 50 placed on the post pad 32. The wafer level package can form a post structure that is more resistant to stresses caused by mounting the package on a board, especially lateral shear stresses.

The semiconductor chip 10 is an electronic component that can be mounted on a board to perform a particular function. The chip pad 12 can be formed on the exterior of the semiconductor chip 10 as a contact terminal for providing electrical connection to a board. Also, in order to form a corrugation for firmly securing the conductive post 50, which electrically connects the wafer level package with the board, an indentation 14 may be formed in the position where the conductive post 50 is to be formed. As illustrated in FIG. 19, this embodiment may include a multiple number of concentric annular indentations 14 in the semiconductor chip 10, for the purpose of forming a corrugation, shaped as concentric circles with repeatedly formed troughs and ridges, in the post pad 32.

A passivation layer 20 made of an oxide film or a nitride film can additionally be formed on one side of the semiconductor chip 10 in which the indentations 14 are formed, to protect the surface of the semiconductor chip 10. In certain examples, the indentations 14 can be formed after forming the passivation layer 20 on one side of the semiconductor chip 10. Thus, the indentation 14 formed in the semiconductor chip 10, as referred to in this specification, encompasses the indentation 14 formed in the passivation layer 20.

The rewiring pattern 30 may serve to electrically connect the chip pad 12 with the conductive post 50. To form the rewiring pattern 30, a conductive material may be selectively built up on one side of the semiconductor chip 10. The rewiring pattern 30 may include a post pad 32, in which a corrugation is formed corresponding with the indentations 14 of the semiconductor chip 10. This arrangement can be used to firmly secure the conductive post 50. In this embodiment, the corrugation may be shaped as concentric circles corresponding with the ring shapes of the indentations 14.

The conductive post 50 may electrically connect the wafer level package with the board and may be formed in the shape of a column placed on the post pad 32. With the conductive post 50 coupled to the corrugation of the post pad 32, the conductive post 50 may be firmly secured to the post pad 32. As such, the conductive post 50 may better resist the stresses that occur when the wafer level package is mounted on a board. In particular, when lateral shear stresses are applied due to the difference in rates of thermal expansion, this structure, which has the lower end of the conductive post 50 lodged in the post pad 32, can effectively prevent the conductive post 50 from being separated from the post pad 32 and from cracking at the contact surfaces.

In order to reinforce the strength of the conductive post 50, a molding material 55 can additionally be stacked on the semiconductor chip 10, surrounding the lateral surfaces of the conductive post 50. The molding material 55 may protect the rewiring pattern 30 and support the conductive post 50. Here, epoxy resin, etc., can be used as the molding material 55.

Also, a conductive bump 60 can be attached to the top of the conductive post 50, to provide electrical connection with the board. In this particular embodiment, the conductive bump 60 may be a hemispherical solder ball that connects the conductive post 50 to the board.

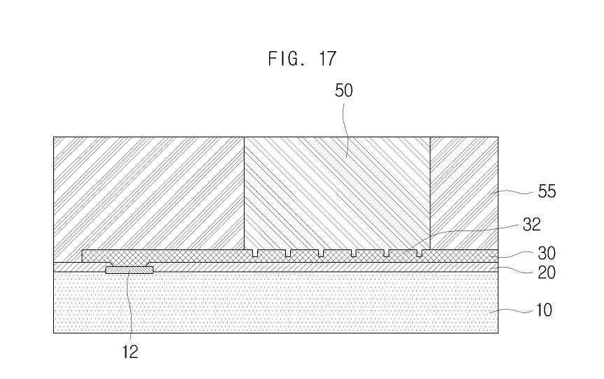

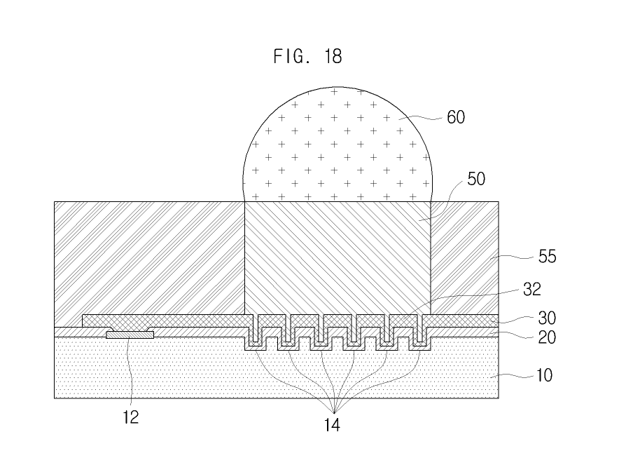

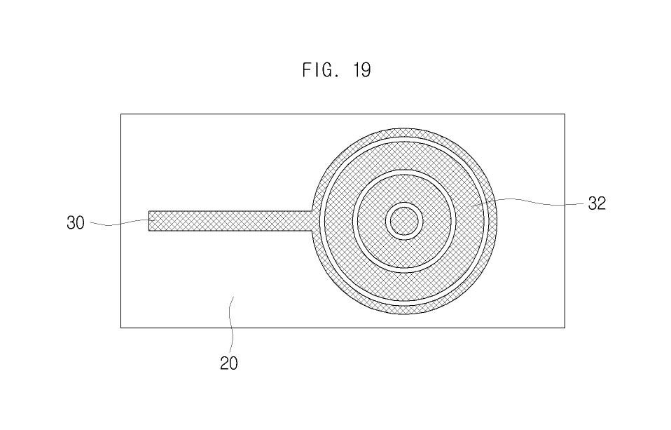

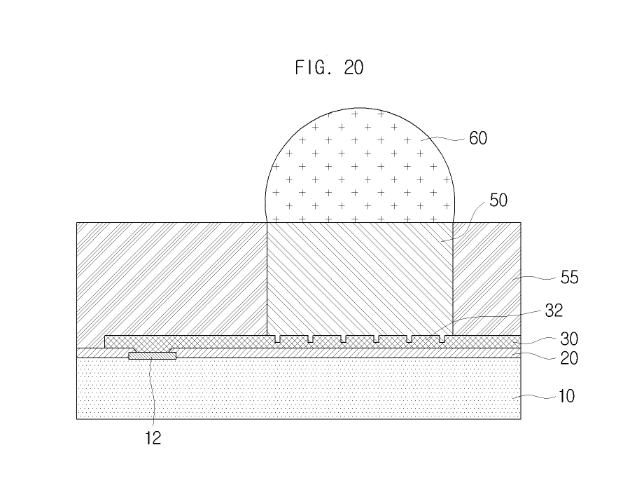

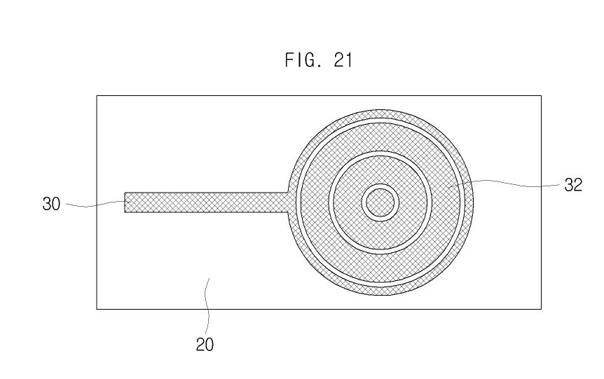

FIG. 20 is a cross-sectional view illustrating a wafer level package according to the second disclosed embodiment of the invention, and FIG. 21 is a plan view illustrating the rewiring pattern 30 in a wafer level package according to the second disclosed embodiment of the invention.

A wafer level package according to the second disclosed embodiment of the invention may include: a semiconductor chip 10, on which a chip pad 12 is formed; a rewiring pattern 30, which is electrically connected with the chip pad 12, and which includes a post pad 32 formed by selective etching so that a corrugation is formed; and a conductive post 50 placed on the post pad 32. The wafer level package can form a post structure that is more resistant to stresses caused by mounting the package on a board, especially lateral shear stresses.

Referring to FIG. 20, a wafer level package according to the second disclosed embodiment may differ from that of the previously disclosed embodiment in that the corrugation may be formed by etching the post pad 32.

This embodiment will be described mainly with respect to elements that are different from those of the first disclosed embodiment.

The semiconductor chip 10 is an electronic component that can be mounted on a board to perform a particular function. The chip pad 12 can be formed on the exterior of the semiconductor chip 10 as a contact terminal for providing electrical connection to a board. Unlike the first disclosed embodiment, there is no indentation 14 formed in the semiconductor chip 10 at the position where the post pad 32 is formed.

A passivation layer 20 made of an oxide film or a nitride film can additionally be formed on one side of the semiconductor chip 10, to protect the surface of the semiconductor chip 10.

The rewiring pattern 30 may serve to electrically connect the chip pad 12 with the conductive post 50. To form the rewiring pattern 30, a conductive material may be selectively built up on one side of the semiconductor chip 10.

Here, the rewiring pattern 30 may include a post pad 32, in which a corrugation may be formed by selective etching. This arrangement can be used to firmly secure the conductive post 50. In this particular embodiment, the corrugation may be shaped as concentric circles, including several concentric indentations 14.

The conductive post 50 may electrically connect the wafer level package with the board and may be formed in the shape of a column placed on the post pad 32. Since the conductive post 50 may be coupled to the corrugation of the post pad 32, the conductive post 50 may be firmly secured to the post pad 32. As such, the conductive post 50 may better resist the stresses that occur when the wafer level package is mounted on a board. In particular, when lateral shear stresses are applied due to the difference in rates of thermal expansion, this structure in which the lower end of the conductive post 50 is lodged in the post pad 32 can effectively prevent the conductive post 50 from being separated from the post pad 32 and from cracking at the contact surfaces.

In order to reinforce the strength of the conductive post 50, a molding material 55 can additionally be stacked on the semiconductor chip 10, surrounding the lateral surfaces of the conductive post 50.

Also, a conductive bump 60 can be attached to the top of the conductive post 50, to provide electrical connection with the board. In this particular embodiment, the conductive bump 60 may be a hemispherical solder ball that connects the conductive post 50 to the board.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments other than those set forth above can be found in the appended claims.

1. A method of manufacturing a wafer level package, the method comprising:
forming an indentation by etching one side of a semiconductor chip, the semiconductor chip having a chip pad formed on the one side thereof;
forming a rewiring pattern by selectively adding a conductive material on one side of the semiconductor chip, the rewiring pattern being electrically connected with the chip pad and comprising a post pad, the post pad having a corrugated shape in correspondence with the indentation;
forming a sacrificial layer on one side of the semiconductor chip such that a window is formed in the sacrificial layer, the window completely or partially uncovering the post pad;
forming a conductive post on the post pad by filling the window with a conductive material; and
removing the sacrificial layer.

2. The method of claim 1, further comprising, after the removing of the sacrificial layer:
stacking a molding material on one side of the semiconductor chip, the molding material surrounding a lateral surface of the conductive post.

3. The method of claim 1, wherein the forming of the sacrificial layer comprises:
stacking a photoresist on one side of the semiconductor chip; and
forming the window completely or partially uncovering the post pad by selectively exposing and developing the photoresist.

4. The method of claim 1, wherein the forming of the conductive post comprises:
performing electroplating using the post pad as an electrode to form the conductive post.

5. A method of manufacturing a wafer level package, the method comprising:
forming a rewiring pattern electrically connected with a chip pad by selectively adding a conductive material on one side of a semiconductor chip, the semiconductor chip having the chip pad formed on the one side thereof;
forming a post pad having a corrugated shape by etching a portion of the rewiring pattern;
forming a sacrificial layer on one side of the semiconductor chip such that a window is formed in the sacrificial layer, the window completely or partially uncovering the post pad;
forming a conductive post on the post pad by filling the window with a conductive material; and
removing the sacrificial layer.

6. The method of claim 5, further comprising, after the removing of the sacrificial layer:
stacking a molding material on one side of the semiconductor chip, the molding material surrounding a lateral surface of the conductive post.

7. The method of claim 5, wherein the forming of the sacrificial layer comprises:
stacking a photoresist on one side of the semiconductor chip; and
forming the window completely or partially uncovering the post pad by selectively exposing and developing the photoresist.

8. The method of claim 5, wherein the forming of the conductive post comprises:
performing electroplating using the post pad as an electrode to form the conductive post.

9-16. (canceled)
